(19) United States
(12) Patent Application Publication
(10) Pub. No.: US 2005/0119982 A1
(43) Pub. Date: Jun. 2, 2005

(54) Information processing apparatus and method

(76) Inventors: Masato Ito, Tokyo (JP); Jun Tani, Kanagawa (JP)

Correspondence Address: William S Frommer;Frommer Lawence & Haug, 745 Fifth Avenue, New York, NY, 10151, US

(21) Appl. No.: 10/483,149

(22) PCT Filed: Jan. 21, 2003
(86) PCT No.: PCT/JP03/00485

(30) Foreign Application Priority Data
May 10, 2002 (JP) 2002-135237

(51) Int. Cl. G06G 7/00; G06F 15/18; H03F 1/26; G06F 15/00; H04B 15/00; G06N 5/02; G06F 17/00

(52) U.S. Cl. 706/20; 702/189; 706/46

(57) ABSTRACT

This invention relates to an information processing device and method that enable classification of a new time series pattern. A time series pattern N of a curve L (21) is inputted to an output layer (13) of a recurrent neural network 1. An intermediate layer (12) has already learned a predetermined time series pattern, and a weighting coefficient corresponding to that time series pattern is held in its neurons. The intermediate layer (12) calculates a parameter corresponding to the time series pattern N on the basis of the weighting coefficient and outputs the calculated parameter from parametric bias nodes (11-2). A comparator unit (31) compares a parameter of a learned pattern stored in a storage unit (32) with the parameter of the time series pattern N and thus classifies the time series pattern N. This invention can be applied to a robot.

### TECHNICAL FIELD

This invention relates to an information processing device and method, and particularly to an information processing device and method that enables classification of time series patterns.

This application claims priority of Japanese Patent Application No. 2002-135237, filed on May 10, 2002, the entirety of which is incorporated by reference herein.

### BACKGROUND ART

Recently, a neural network has been studies as a mode related to human and animal brains. In a neural network, as a predetermined pattern is learned in advance, whether inputted data corresponds to the learned pattern or not can be identified.

Conventionally, in the case of classifying patterns using such a neural network, independent sub-modules are caused to learn the plural patterns. The outputs of the respective sub-modules are weighted at a predetermined rate and constitute the output of the entire module.

If an unknown pattern is inputted, it is known to estimate a coefficient value for weighting the outputs of the respective sub-modules to generate a pattern that is most approximate to the inputted pattern, as the output of the entire module, and classify a newly provided pattern in accordance with the value.

However, such a classifying method has a problem that a time series pattern as a classification target cannot be classified on the basis of the relation with already learned patterns. That is, only a pattern expressed by a linear sum of learned patterns can be classified and a pattern expressed by a nonlinear sum cannot be classified.

### DISCLOSURE OF THE INVENTION

In view of the foregoing status of the art, it is an object of the present invention to enable classification of a pattern based on the relation with already learned patterns. More preferably, the linear relation is based on a dynamic structure in a common dynamic system. However, the present invention is not limited to this.

An information processing device according to the present invention includes: input means for inputting a time series pattern to be classified; and modeling means for modeling each of plural time series patterns inputted from the input means on the basis of a common nonlinear dynamic system having one or more feature parameters that can be operated from outside; wherein when a new time series pattern is inputted, further modeling is performed, and a feature parameter obtained by the modeling and the already obtained feature parameters are compared with each other, thereby classifying the new time series pattern.

The nonlinear dynamic system can be a recurrent neural network with an operating parameter.

The feature parameter can indicate a dynamic structure of the time series pattern in the nonlinear dynamic system.

An information processing method according to the present invention includes: an input step of inputting a time series pattern to be classified; and a modeling step of modeling each of plural time series patterns inputted by the processing of the input step on the basis of a common nonlinear dynamic system having one or more feature parameters that can be operated from outside; wherein when a new time series pattern is inputted, further modeling is performed, and a feature parameter obtained by the modeling and the already obtained feature parameters are compared with each other, thereby classifying the new time series pattern.

A program in a program storage medium according to the present invention includes: an input step of inputting a time series pattern to be classified; and a modeling step of modeling each of plural time series patterns inputted by the processing of the input step on the basis of a common nonlinear dynamic system having one or more feature parameters that can be operated from outside; wherein when a new time series pattern is inputted, further modeling is performed, and a feature parameter obtained by the modeling and the already obtained feature parameters are compared with each other, thereby classifying the new time series pattern.

A program according to the present invention includes: an input step of inputting a time series pattern to be classified; and a modeling step of modeling each of plural time series patterns inputted by the processing of the input step on the basis of a common nonlinear dynamic system having one or more feature parameters that can be operated from outside; wherein when a new time series pattern is inputted, further modeling is performed, and a feature parameter obtained by the modeling and the already obtained feature parameters are compared with each other, thereby classifying the new time series pattern.

In the information processing device and method, the program storage medium and the program according to the present invention, feature parameters obtained by modeling plural time series patterns and a feature parameter obtained by modeling a new time series pattern are compared with each other.

### BRIEF DESCRIPTION OF THE DRAWINGS

FIG. 1 is a view showing the structure of a recurrent neural network to which the present invention is applied.

FIG. 2 is a flowchart for explaining learning processing of the recurrent neural network of FIG. 1.

FIG. 3 is a flowchart for explaining coefficient setting processing of the recurrent neural network of FIG. 1.

FIG. 4A is a view showing an exemplary time series pattern having different amplitude and the same cycle.

FIG. 4B is a view showing an exemplary time series pattern having different amplitude and the same cycle.

FIG. 4C is a view showing an exemplary time series pattern having different amplitude and the same cycle.

FIG. 5A is a view showing an exemplary time series pattern having a different cycle and the same amplitude.

FIG. 5B is a view showing an exemplary time series pattern having a different cycle and the same amplitude.

FIG. 5C is a view showing an exemplary time series pattern having a different cycle and the same amplitude.

FIG. 6 is a view showing an exemplary learned pattern.

FIG. 7 is a view showing an exemplary learned pattern.

FIG. 8 is a flowchart for explaining time series pattern generation processing of the recurrent neural network of FIG. 1.

FIG. 9 is a view showing an exemplary time series pattern to be generated.

FIG. 10 is a view showing the structure of a recurrent neural network to which the present invention is applied.

FIG. 11 is a view showing learned patterns.

FIG. 12 is a flowchart for explaining classification processing in the recurrent neural network of FIG. 10.

FIG. 13 is a block diagram showing the structure of a personal computer to which the present invention is applied.

### BEST MODE FOR CARRYING OUT THE INVENTION

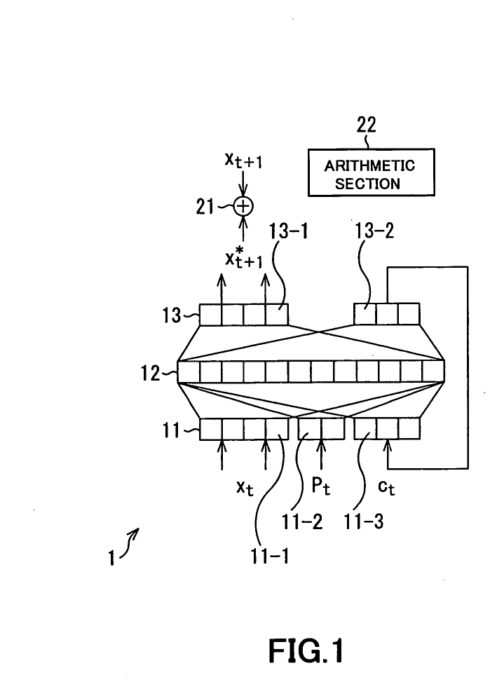

FIG. 1 shows an exemplary structure of a recurrent neural network to which the present invention is applied. This recurrent neural network (RNN) 1 includes an input layer 11, an intermediate layer (hidden layer) 12, and an output layer 13. Each of these input layer 11, intermediate layer 12 and output layer 13 includes an arbitrary number of neurons.

Data xₜ related to a time series pattern is inputted to neurons 11-1, which constitute a part of the input layer 11. Specifically, for example, the data is related to a time series pattern such as a human physical movement pattern (for example, locus of movement of the hand position) acquired by image processing based on camera images. Pₜ is a vector and its dimension is arbitrary depending on the time series pattern. The parameter Pₜ is inputted to parametric bias nodes 11-2, which are neurons constituting a part of the input layer 11. The number of parametric bias nodes is one or more. It is desired that the number of parametric bias nodes is sufficiently small with respect to the total number of neuron that constitute the recurrent neural network and decide the number of weight matrixes, that is, a parameter of model decision means. In this embodiment, the number of parametric bias nodes is about one to two where the total number of such neurons is approximately 50. However, the invention of this application is not limited to this specific numbers. The parametric bias nodes are adapted for modulating a dynamic structure in a nonlinear dynamic system. In this embodiment, the parametric bias nodes are nodes that function to modulate a dynamic structure held by the recurrent neural network. However, this invention is not limited to the recurrent neural network. Moreover, data outputted from neurons 13-2, which constitute a part of the output layer 13, is fed back to neurons 11-3, which constitute a part of the input layer 11, as a context Cₜ expressing the internal state of the RNN 1. The context Cₜ is a common term related to the recurrent neural network and can be described in a reference literature (Elman, J. L. “Finding structure in time”, Cognitive Science, 14, (1990), pages 179-211) and the like.

The neurons of the intermediate layer 12 execute weighted addition processing to inputted data and processing to sequentially output the processed data to the subsequent stage. Specifically, after arithmetic processing (arithmetic processing based on a nonlinear function) with a predetermined weighting coefficient is performed to the data xₜ, Pₜ, and Cₜ, the processed data are outputted to the output layer 13. In this embodiment, for example, arithmetic processing based on a function having a nonlinear output characteristic such as a sigmoid function is performed to the input of a predetermined weighted sum of xₜ, Pₜ, and Cₜ, and then the processed data is outputted to the output layer 13.

Neurons 13-1, which constitute a part of the output layer 13, output data x*ₜ₊₁ corresponding to input data.

The RNN 1 also has an arithmetic unit 21 for learning based on back propagation. An arithmetic section 22 performs processing to set a weighting coefficient for the RNN 1.

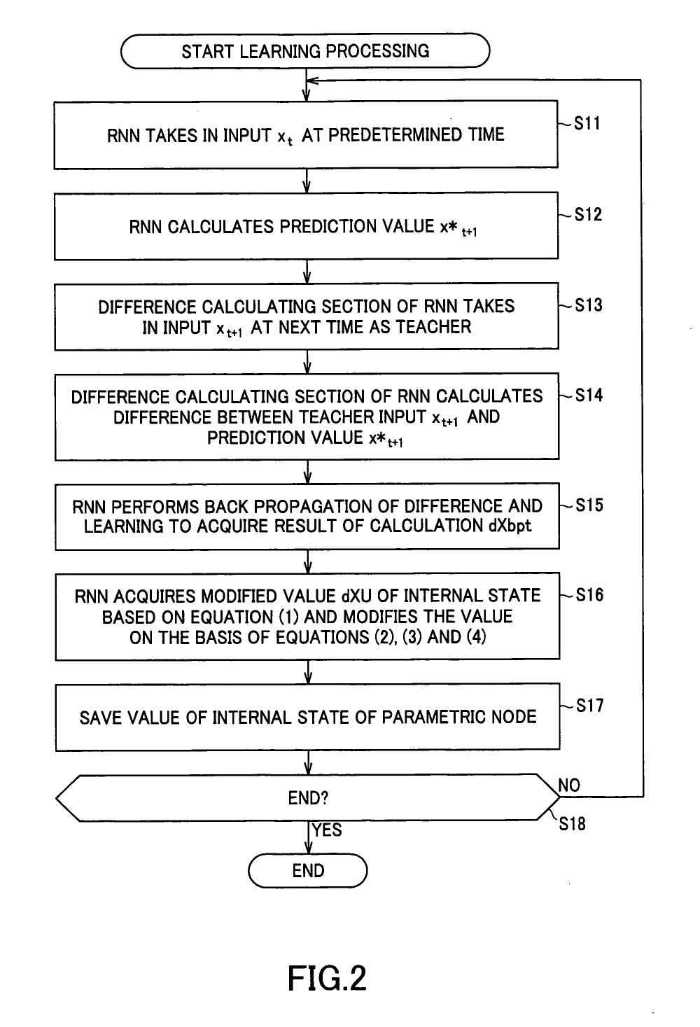

The learning processing of the RNN 1 will now be described with reference to flowchart of FIG. 2.

The processing shown in the flowchart of FIG. 2 is executed with respect to each time series pattern to be learned. In other words, virtual RNNs corresponding to the number of time series patterns to be learned are prepared and the processing of FIG. 2 is executed with respect to each of the virtual RNNs.

After the processing shown in the flowchart of FIG. 2 is executed with respect to each of the virtual RNNs and a time series pattern is learned with respect to each virtual RNN, processing to set a coefficient to the actual RNN 1 is executed. In the following description, however, each virtual RNN is described as the actual RNN 1.

First, at step S11, the neurons 11-1 of the input layer 11 of the RNN 1 takes in an input xₜ at a predetermined time t. At step S12, the intermediate layer 12 of the RNN 1 performs arithmetic processing corresponding to a weighting coefficient to the input xₜ, and a prediction value x*ₜ₊₁ of a time series t+1 in the inputted time series pattern is outputted from the neurons 13-1 of the output layer 13.

At step S13, the arithmetic unit 21 takes in an input xₜ₊₁ at the next time t+1, as teacher data. At step S14, the arithmetic unit 21 calculates the difference between the teacher input x*ₜ₊₁ taken in by the processing of step S13 and the prediction value x*ₜ₊₁ calculated by the processing of step S12.

At step S15, the RNN 1 inputs the difference calculated by the processing of step S14 from the neurons 13-1 of the output layer 13 and propagates it to the intermediate layer 12 and then to the input layer 11, thus performing learning processing. The result of calculation dX_{bpt} is thus acquired.

At step S16, the intermediate layer 12 acquires a modified value dXU of the internal state based on the following equation (1).

$${dXU}_{t} = {k}_{bp} \cdot {\sum }_{t \frac{1}{2}}^{t + \frac{1}{2}} {dX}_{bpt} + {k}_{nb} \cdot ( {XU}_{t + 1} - {XU}_{t} + {XU}_{t - 1} - {XU}_{t} ) \qquad ( 1 )$$

Moreover, the intermediate layer 12 modifies the modified value dXU on the basis of the following equations (2) to (4).
d1XUₜ=ε·dXUₜ+momentum·d1XUₜ (2)
XUₜ=XUₜ+d1XUₜ (3)
Xₜ=sigmoid(XUₜ) (4)

At step S17, the parametric nodes 11-2 execute processing to save the value of the internal state.

Next, at step S18, the RNN 1 judges whether to end the learning processing or not. If the learning processing is not to be ended, the RNN 1 returns to step S11 and repeats execution of the subsequent processing.

If it is judged at step S18 that the learning processing is to be ended, the RNN 1 ends the learning processing.

As the learning processing as described above is performed, one time series pattern is learned with respect to a virtual RNN.

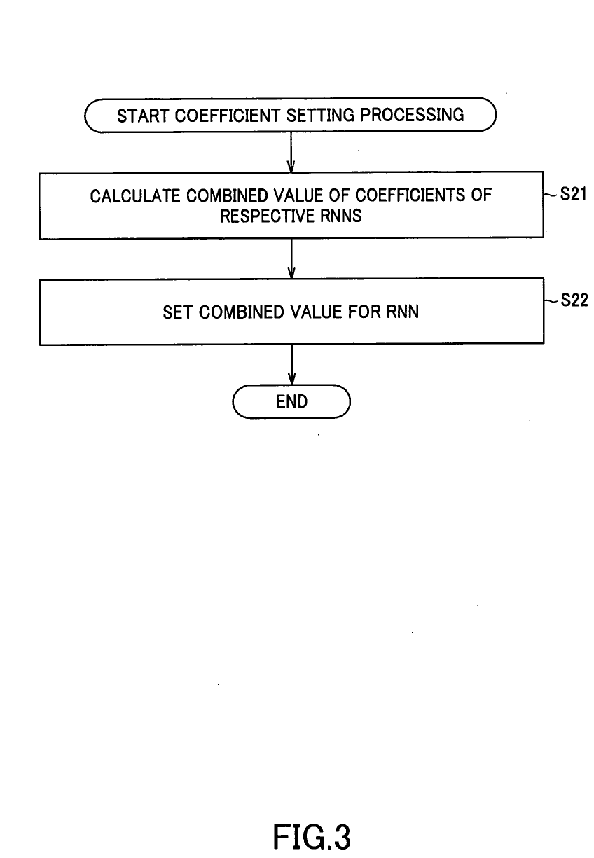

After the learning processing as described above is performed for the virtual RNNs corresponding to the number of learning patterns, processing to set the weighting coefficient acquired from the learning processing, for the actual RNN 1, is performed. FIG. 3 shows the processing in this case.

At step S22, the arithmetic section 22 calculates a combined value of the coefficients acquired as a result of executing the processing shown in the flowchart of FIG. 2 with respect to each virtual RNN. As this combined value, for example, an average value can be used. That is, an average value of the weighting coefficients of the respective virtual RNNs is calculated here.

Next, at step S22, the arithmetic section 22 executes processing to set the combined value (average value) calculated by the processing of step S21, as a weighting coefficient for the neurons of the actual RNN 1.

Thus, the coefficient acquired by learning the plural time series patterns is set for each neuron of the intermediate layer 12 of the actual RNN 1.

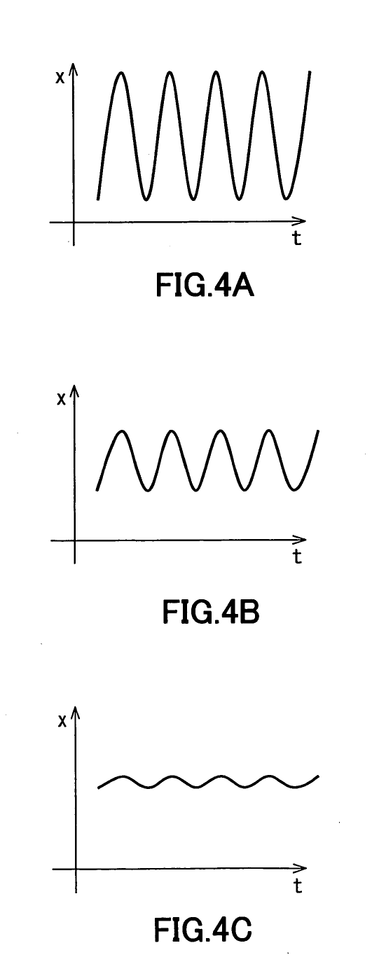

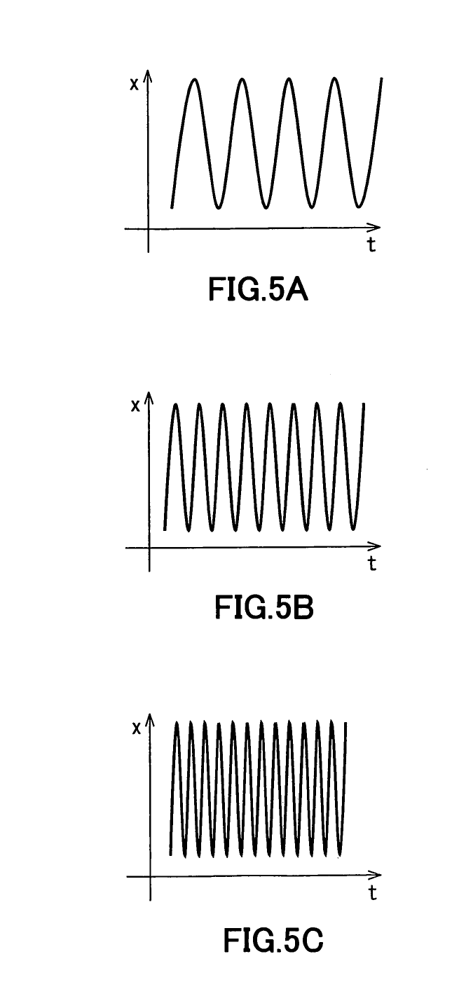

The weighting coefficient for each neuron of the intermediate layer 12 holds information related to a shareable dynamic structure in order to generate plural teaching time series patterns, and the parametric bias nodes hold necessary information for switching the shareable dynamic structure to a dynamic structure suitable for generating each teaching time series pattern. An example of the “shareable dynamic structure” will now be described. For example, as shown in FIGS. 4A to 4C, when a time series pattern A and a time series pattern B having different amplitude and the same cycle are inputted, the cycle of an output time series pattern C is the shareable dynamic structure. On the other hand, as shown in FIGS. 5A to 5C, when a time series pattern A and a time series pattern B having different cycles and the same amplitude are inputted, the amplitude of an output time series pattern C is the shareable dynamic structure. However, the invention of this application is not limited to these examples.

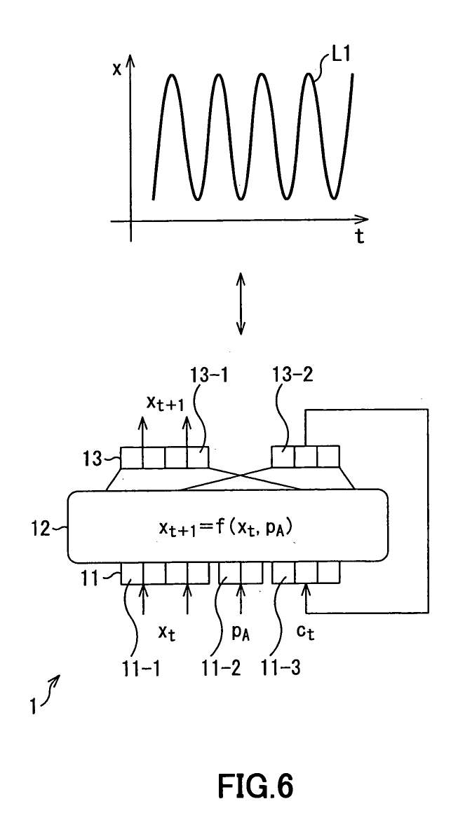

For example, as first data is inputted and learned, a time series pattern indicated by a curve L1 having relatively large amplitude is learned, as shown in FIG. 6.

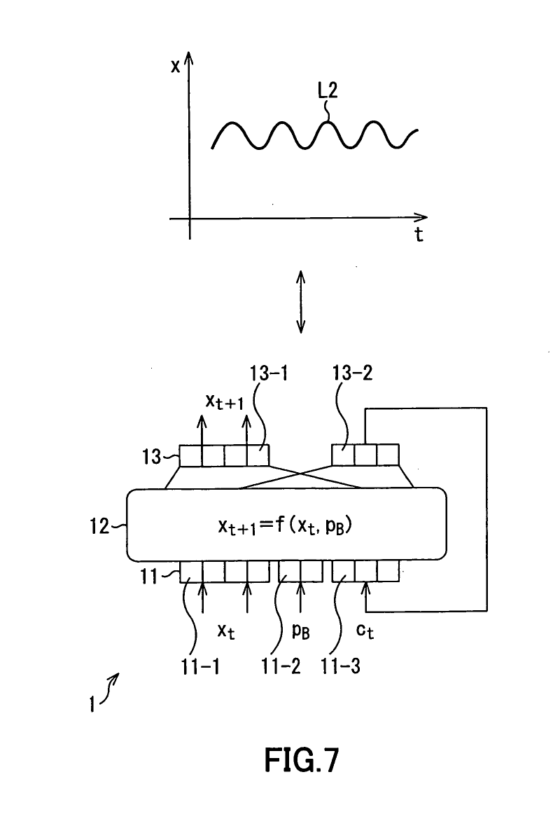

Similarly, as second data is inputted and learned, a time series pattern indicated by a curve L2 having relatively small amplitude is learned, as shown in FIG. 7.

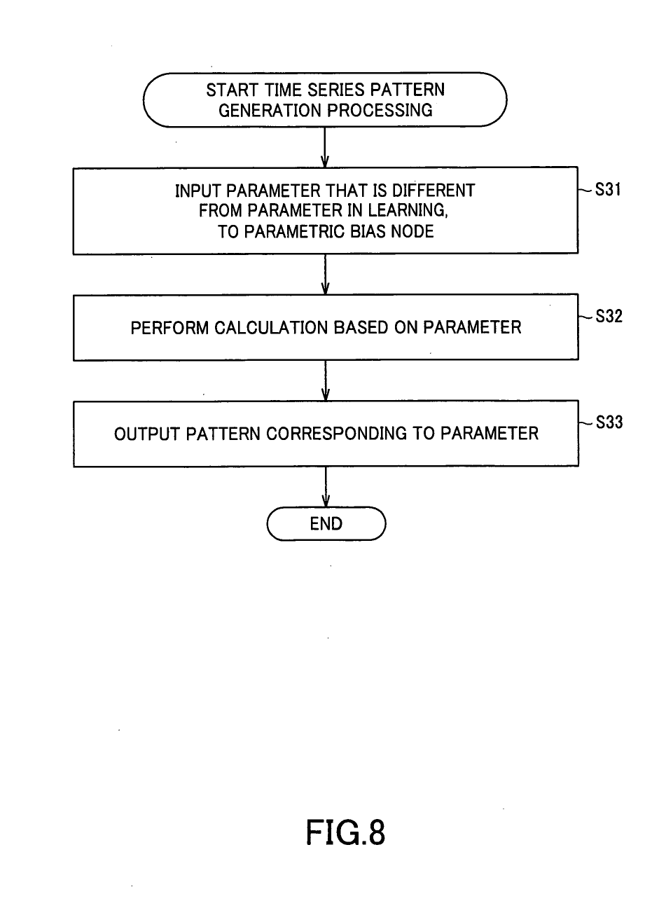

When generating a new time series pattern in the RNN 1 after such time series patterns are learned, processing as shown in the flowchart of FIG. 8 is executed.

Specifically, first, at step S31, the parametric bias nodes 11-2 input a parameter that is different from the parameter in learning. At step S32, the intermediate layer 12 performs calculation based on a weighting coefficient with respect to the parameter inputted to the parametric bias nodes 11-2 by the processing of step S31. Specifically, inverse operation of the operation for calculating the parameter value in learning is carried out.

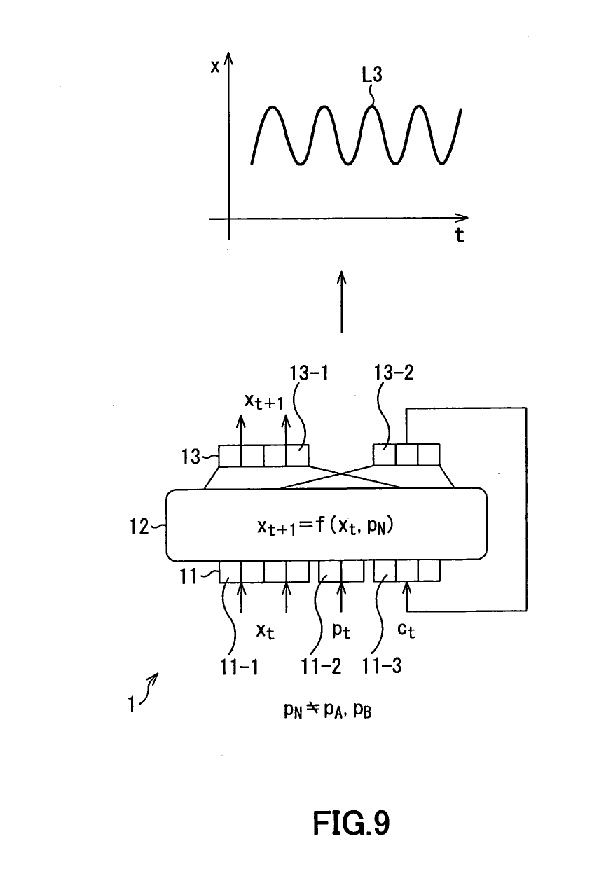

FIG. 9 shows an example in the case a parameter P_{N} is inputted as a parameter Pₜ to the parametric bias nodes 11-2 of the RNN 1 after the RNN 1 is caused to learn the time series patterns shown in FIGS. 6 and 7. This parameter P_{N} has a value that is different from a parameter P_{A} outputted to the parametric bias nodes 11-2 in pattern learning of FIG. 6 and a parameter P_{B} outputted in time series pattern learning shown in FIG. 7. That is, in this case, the value of the parameter P_{N} is an intermediate value between the values of the parameters P_{A} and P_{B}.

In this case, the time series pattern outputted from the neurons 13-1 of the output layer 13 is a time series pattern indicated by a curve L3 in FIG. 9. The amplitude of this curve L3 is smaller than the amplitude of the curve L1 of the time series pattern A shown in FIG. 6 and larger than the amplitude of the curve L2 of the time series pattern B shown in FIG. 7. In other words, the amplitude of the curve L3 has an intermediate value between the amplitude of the curve L1 and the amplitude of the curve L2. That is, in this example, the curve L3, which is an intermediate curve between the curve L1 and the curve L2 shown in FIGS. 6 and 7, is linearly interpolated.

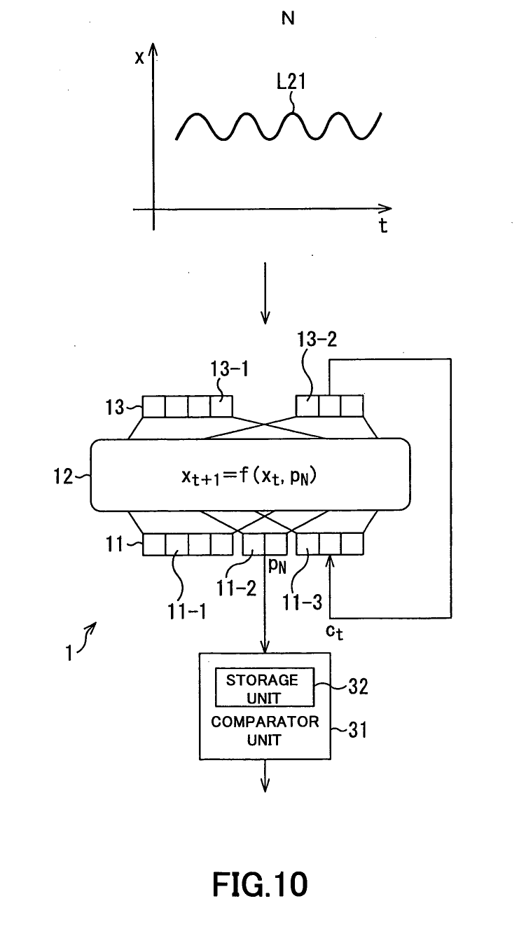

A time series pattern corresponding to parametric bias (parameter) can be thus generated. Therefore, conversely, a parameter corresponding to a given time series pattern can be acquired and the time series pattern can be classified on the basis of the parameter. In this case, the output of the parametric bias nodes 11-2 is supplied to a comparator unit 31, as shown in FIG. 10. The comparator unit 31 has a storage unit 32 therein, and time series parameters (parametric bias) corresponding to time series patterns at the time of learning are stored in the storage unit 32.

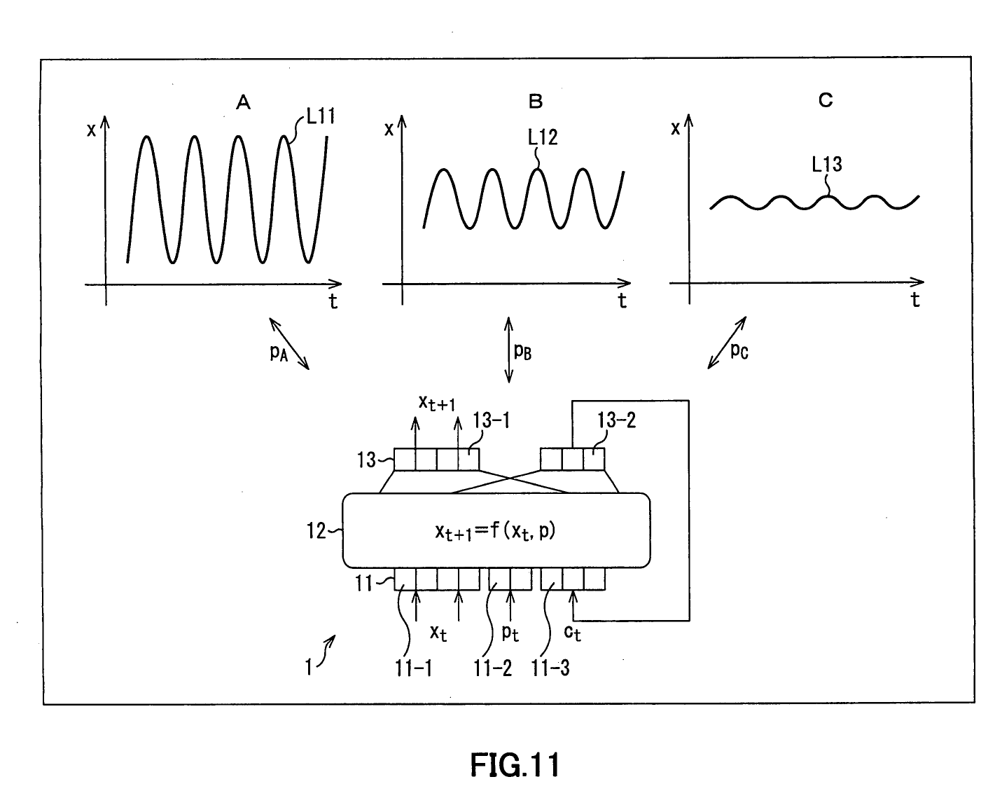

For example, it is assumed that the RNN 1 is caused to learn three time series patterns in advance, that is, a time series pattern A indicated by a curve L11, a time series pattern B indicated by a curve L12, and time series indicated by a curve L13, as shown in FIG. 11. When the time series pattern A corresponding to the curve L11 is learned, a parameter P_{A} is outputted from the parametric bias nodes 11-2. When the time series pattern B corresponding to the curve L12 is learned, a parameter P_{B} is outputted from the parametric bias nodes 11-2. When the time series pattern C corresponding to the curve L13 is learned, a parameter P_{C} is outputted from the parametric bias nodes 11-2. The storage unit 32 stores these parameters P_{A}, P_{B} and P_{C}.

In the example of FIG. 11, all of the time series pattern A indicated by the curve L11, the time series pattern B indicated by the curve L12 and the time series pattern C indicated by the curve L13 are time series patterns based on sine-wave signals and have the same frequency. However, the time series pattern A corresponding to the curve L11 has the largest amplitude and the time series pattern C indicated by the curve L13 has the smallest amplitude. The time series pattern B indicated by the curve L12 has amplitude of an intermediate value between the two.

The values of the parameters P_{A}, P_{B} and P_{C} are proportional to the magnitude of amplitude (that is, expressed by linear sum). Therefore, of the three parameters, the parameter P_{A} has the largest value and the parameter P_{B} has the smallest value. The parameter P_{C} has an intermediate value between the two.

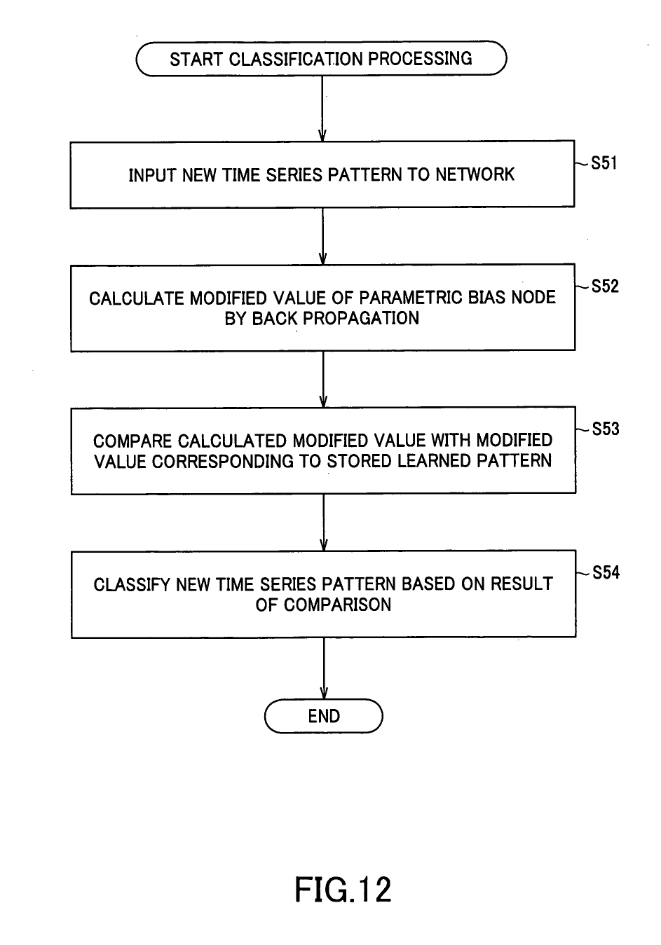

Next, time series pattern classification processing will be described with reference to the flowchart of FIG. 12. First, at step S51, a new time series pattern to be classified is inputted to the neurons 13-1 of the output layer 13. In the example of FIG. 10, a pattern N indicated by a curve L21 is inputted.

At step S52, the intermediate layer 12 finds a modified value of parametric bias by a back propagation method. Specifically, the intermediate layer 12 performs calculation based on the back propagation method and a parameter (parametric bias) P_{N} acquired as the result of the calculation is outputted from the parametric bias nodes 11-2.

At step S53, the comparator unit 31 executes processing to compare the value of parametric bias acquired by the processing of step S42 with modified values corresponding to the learned patterns stored in advance in the storage unit 32. Specifically, since three time series patterns, that is, the time series pattern A, the time series pattern B and the time series pattern C shown in FIG. 11, are learned as learned patterns, the parameters P_{A}, P_{B} and P_{C} are stored in the storage unit 32. Thus, the comparator unit 31 compares the value of the parameter P_{N} acquired by the processing of step S52 with the parameters P_{A}, P_{B} and P_{C} stored in the storage unit 32.

At step S54, the comparator unit 31 classifies the time series pattern (new time series pattern) inputted at step S51, on the basis of the result of the comparison of step S53.

As described above, the parameter value is proportional to the magnitude of amplitude. The amplitude of the time series pattern N indicated by the curve L21 in FIG. 10 is smaller than the amplitude of the time series pattern B indicated by the curve L12 in FIG. 11 and larger than the amplitude of the time series pattern C indicated by the curve L13. Therefore, the parameter P_{N} of the time series pattern N has a value larger than the value of the parameter P_{C} of the time series pattern C and small than the value of the parameter P_{B} of the time series pattern B. Thus, the comparator unit 31 classifies the time series pattern N of the curve L21 as an intermediate time series pattern between the time series pattern B of the curve L12 and the time series pattern C of the curve L13.

By thus calculating a parameter for an inputted time series pattern to be classified on the basis of coefficients obtained by learning plural time series patterns, and then comparing the parameter with the parameters obtained by learning the plural time series patterns, it is possible to classify the unlearned time series pattern (expressed by a nonlinear sum of learned time series patterns).

That is, this classification is performed on the basis of the relation with time series patterns that have been learned in advance.

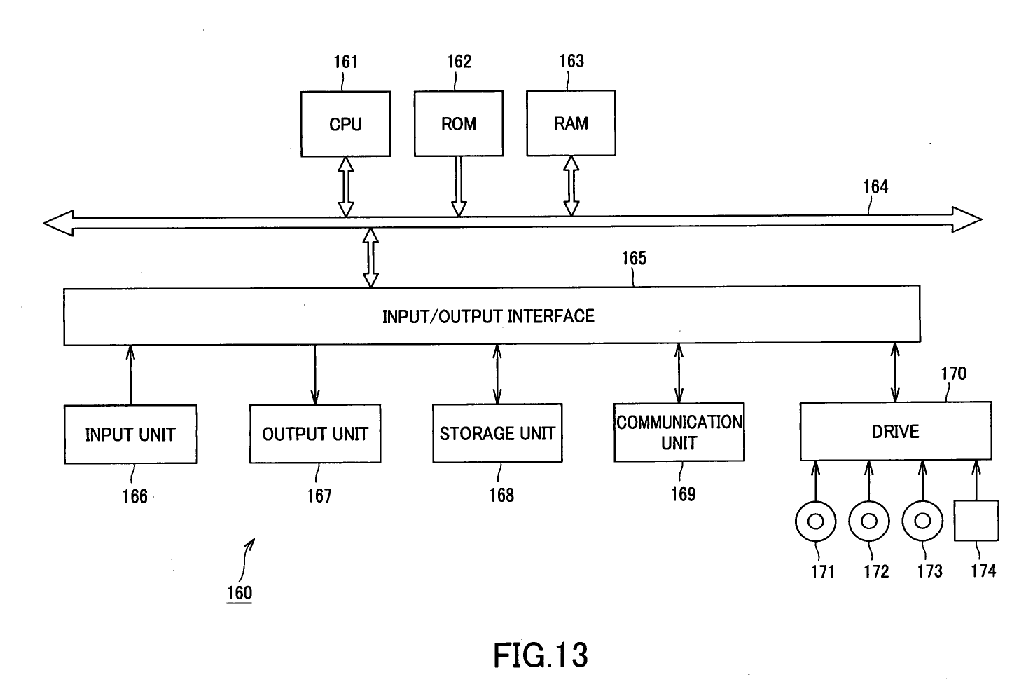

The above-described series of processing, which can be executed by hardware, can also be executed by software. In this case, for example, a personal computer 160 as shown in FIG. 13 is used.

In FIG. 13, a CPU (central processing unit) 161 executes various processing in accordance with programs stored in a ROM (read-only memory) 162 and programs loaded from a storage unit 168 to a RAM (random-access memory) 163. In the RAM 163, necessary data for the CPU 161 to execute various processing are properly stored.

The CPU 161, the ROM 162 and the RAM 163 are interconnected via a bus 164. Also an input/output interface 165 is connected to this bus 164.

The input/output interface 165 is connected with an input unit 166 including a keyboard, a mouse and the like, an output unit 167 including a display such as a CRT or LCD and a speaker, a storage unit 168 including a hard disk, and a communication unit 169 including a modem, a terminal adaptor and the like. The communication unit 169 performs communication processing via a network.

The input/output interface 165 is also connected with a drive 170, when necessary. A magnetic disk 171, an optical disc 172, a magneto-optical disc 173 or a semiconductor memory 174 is properly loaded on the drive 170, and a computer program read from the medium is installed into the storage unit 168, when necessary.

In the case of executing a series of processing by software, a program constituting the software is installed into the personal computer 160 from a network or a recording medium.

This recording medium may be not only a package medium such as the magnetic disk 171 (including a floppy disk), the optical disc 172 (including CD-ROM (compact disc read-only memory) and DVD (digital versatile disk)), the magneto-optical disc 173 (including MD (mini-disc)) or the semiconductor memory 174 which is distributed to provide the program to the user separately from the device and in which the program is recorded, but also the ROM 162 or the hard disk included in the storage unit 168 which is provided to the user in the form of being incorporated in the device and in which the program is recorded, as shown in FIG. 13.

In this specification, the step of describing a program to be recorded to a recording medium includes the processing performed in time series in the described order and also includes processing executed in parallel or individually, though not necessarily in time series.

While the invention has been described in accordance with certain preferred embodiments thereof illustrated in the accompanying drawings and described in the above description in detail, it should be understood by those ordinarily skilled in the art that the invention is not limited to the embodiments, but various modifications, alternative constructions or equivalents can be implemented without departing from the scope and spirit of the present invention as set forth and defined by the appended claims.

Industrial Applicability

As is described above, with the information processing device and method, the program storage medium and the program according to the present invention, time series patterns can be classified. Particularly, by comparing a feature parameter obtained by modeling a new time series pattern with feature parameters of plural time series patterns that have already been modeled, it is possible to classify the new time series pattern.

1. An information processing device for classifying a time series pattern, comprising:
input means for inputting a time series pattern to be classified; and
modeling means for modeling each of plural said time series patterns inputted from the input means on the basis of a common nonlinear dynamic system having one or more feature parameters that can be operated from outside;
wherein when a new time series pattern is inputted, said modeling is further performed, and a feature parameter obtained by the modeling and the already obtained feature parameters are compared with each other, thereby classifying the new time series pattern.

2. The information processing device as claimed in claim 1, wherein the nonlinear dynamic system is a recurrent neural network with an operating parameter.

3. The information processing device as claimed in claim 1, wherein the feature parameter indicates a dynamic structure of the time series pattern in the nonlinear dynamic system.

4. An information processing method for an information processing device for classifying a time series pattern, the method comprising:
an input step of inputting a time series pattern to be classified; and
a modeling step of modeling each of plural time series patterns inputted by the processing of the input step on the basis of a common nonlinear dynamic system having one or more feature parameters that can be operated from outside;
wherein when a new time series pattern is inputted, said modeling is further performed, and a feature parameter obtained by the modeling and the already obtained feature parameters are compared with each other, thereby classifying the new time series pattern.

5. A program storage medium having a computer-readable program stored therein, the program being adapted for an information processing device for classifying a time series pattern, the program comprising:
an input step of inputting a time series pattern to be classified; and
a modeling step of modeling each of plural time series patterns inputted by the processing of the input step on the basis of a common nonlinear dynamic system having one or more feature parameters that can be operated from outside;
wherein when a new time series pattern is inputted, said modeling is further performed, and a feature parameter obtained by the modeling and the already obtained feature parameters are compared with each other, thereby classifying the new time series pattern.

6. A computer program for controlling an information processing device for classifying a time series pattern, the program comprising:
an input step of inputting a time series pattern to be classified; and
a modeling step of modeling each of plural time series patterns inputted by the processing of the input step on the basis of a common nonlinear dynamic system having one or more feature parameters that can be operated from outside;
wherein when a new time series pattern is inputted, said modeling is further performed, and a feature parameter obtained by the modeling and the already obtained feature parameters are compared with each other, thereby classifying the new time series pattern.
